(19) United States
(12) Patent Application Publication
(10) Pub. No.: US 2009/0080161 A1
(43) Pub. Date: Mar. 26, 2009

(54) HEAT DISSIPATION DEVICE FOR COMPUTER ADD-ON CARD

(75) Inventors: XUE-WEN PENG, Shenzhen (CN); RUI-HUA CHEN, Shenzhen (CN)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/861,686

(22) Filed: Sep. 26, 2007

(51) Int. Cl. H05K 7/20

(52) U.S. Cl. 361/719; 361/700

(57) ABSTRACT

A heat dissipation device for dissipating heat generated by an electronic component mounted on an add-on card includes a first heat dissipation unit, a second heat dissipation unit, a third heat dissipation unit and a heat pipe. The heat pipe has an evaporating portion thermally connecting with the electronic component via the first dissipation unit, and two oppositely extending condensing portions extending through and thermally connecting with the second and third heat dissipation units. The second and third heat dissipation units are positioned at a common lengthwise side of the graphics card and separated from each other. The second and third heat dissipation units each have an L-shaped configuration. The heat pipe has two connection portions connecting the evaporating portion with the condensing portions, respectively. The connecting portions together with the evaporating portion form a U-shaped configuration.

### BACKGROUND OF THE INVENTION

1. Field of the Invention

The present invention relates to a heat dissipation device, and more particularly to a heat dissipation device mounted onto an add-on card for dissipating heat generated by the add-on card.

2. Description of Related Art

In order to enable computers to rapidly process graphics and games, add-on cards, more specifically graphics cards are often installed in the computers. Such cards each comprise a separate processor, called GPU (graphics processor unit). The GPU generates a large amount of heat during operation. When the temperature of the GPU exceeds a certain level, the GPU may malfunction, or in the worst case fail outright. For this reason, a heat sink having a heat pipe engaged therewith is installed on the GPU to dissipate the heat generated by the GPU and other electronic components adjacent to it into ambient air.

A typical heat sink is manufactured to have a bulky volume with a large height and comprises a base for receiving heat from the GPU and a plurality of fins extending from the base to dissipate the heat to ambient air. A heat pipe generally comprises an evaporating portion engaged with the base and a condensing portion engaged with the fins, thereby to transfer heat from the base to the fins remote from the base. However, it is impractical to install such a large, high-capacity heat sink to the graphics card because the space between the add-on cards is usually so narrow that a heat sink with a bulky volume can not be positioned therebetween. This has adversely affected the heat dissipation of the add-on cards.

What is needed is a heat dissipation device which has an improved configuration for effectively making use of the space between the add-on cards to dissipate heat generated by the electronic component on the add-on cards.

### SUMMARY OF THE INVENTION

A heat dissipation device for dissipating heat generated by an electronic component mounted on an add-on card, includes a first heat dissipation unit, a second heat dissipation unit, a third heat dissipation unit and a heat pipe thermally connecting the first heat dissipation unit with the second and third heat dissipation units. The first heat dissipation unit is attached to a top surface of the electronic component. The second heat dissipation unit includes a first portion located over a top surface of the add-on card, and a second portion extending perpendicularly and downwardly from the first portion to a position beyond a bottom surface of the add-on card. The heat pipe includes an evaporating portion received in the first heat dissipation unit, and first and second condensing portions. The first condensing portion extends through the second heat dissipation unit at a joint of the first portion and the second portion of the second heat dissipation unit. The second condensing portion extends through the third heat dissipation unit. The first and second condensing portions extend in opposite directions.

Other advantages and novel features will become more apparent from the following detailed description of preferred embodiments when taken in conjunction with the accompanying drawings, in which:

### BRIEF DESCRIPTION OF THE DRAWINGS

FIG. 1 is an isometric view of a heat dissipation device in accordance with a preferred embodiment of the present invention, the heat dissipation device being assembled to a graphics card;

FIG. 2 is an exploded, isometric view of FIG. 1; and

FIG. 3 is a view similar to FIG. 2, but shown from a different aspect.

### DETAILED DESCRIPTION OF THE INVENTION

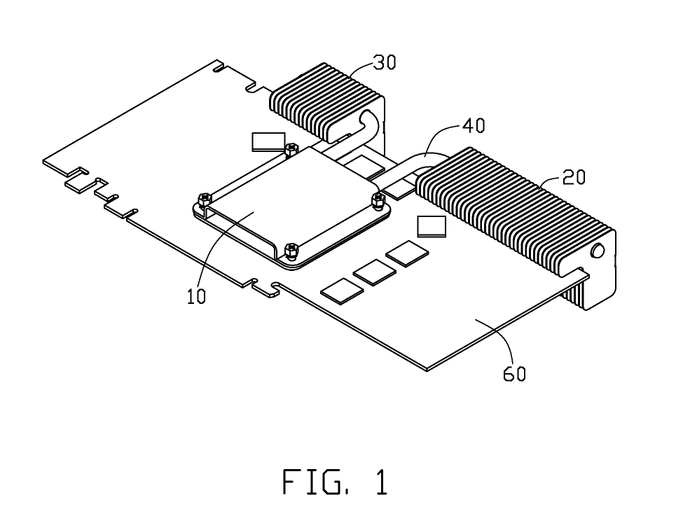

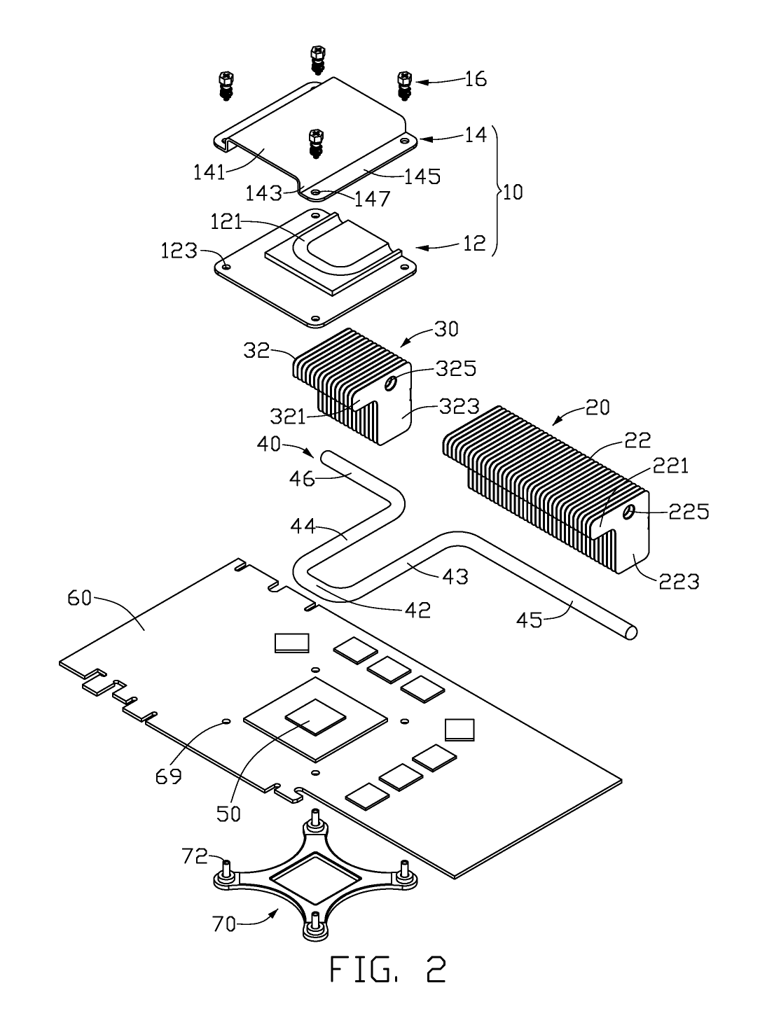

FIGS. 1-2 illustrate a heat dissipation device for dissipating heat generated by an electronic component 50 mounted on a top surface (not labeled) of a graphics card 60. The heat dissipation device comprises a first heat dissipation unit 10, a second heat dissipation unit 20, a third heat dissipation unit 30 and a heat pipe 40 connecting the first, the second and the third heat dissipation units 10, 20, 30 to remove heat from the electronic component 50. The graphics card 60 has a bottom surface (not labeled) located at an opposite side of the top surface and four spaced through holes 69 defined therein, surrounding the electronic component 50.

The heat pipe 40 comprises an evaporating portion 42, a pair of condensing portions 45, 46 and a pair of parallel connecting portions 43, 44 interconnecting the evaporating portion 42 with the condensing portions 45, 46. The evaporating portion 42 is straight. The connecting portions 43, 44 extend rearwards from opposite ends of the evaporating portion 42. The connecting portions 43, 44 have the same length. The condensing portions 45, 46 extend perpendicularly and outwardly from free ends of the connecting portions 43, 44, respectively. The condensing portions 45, 46 are separately located at a lengthwise side of the add-on card and oriented towards opposite directions. The condensing portion 45 has a length longer than that of the condensing portion 46. The evaporating portion 42 and the connecting portions 43, 44 cooperatively form a U-shaped configuration.

The first heat dissipation unit 10 comprises a base plate 12 attached on a top surface of the electronic component 50 and a clamping member 14 engaging with the base plate 12. Screws 16 are used to secure the clamping member 14 to the base plate 12. The base plate 12 is rectangular and made of metal. A U-shaped groove 121 is defined at a top surface and located at an end of the base plate 12 to receive the evaporating portion 42 and parts of the connecting portions 43, 44 of the heat pipe 40 therein. Four through holes 123 are defined in corners of the base plate 12 and aligned with through holes 69 of the graphics card 60.

The clamping member 14 is made of a metal sheet and comprises a flat top portion 141, two side portions 143 extending perpendicularly and downwardly from opposite sides of the top portion 141 and two connecting portions 145 extend perpendicularly and outwardly from opposite sides of the side portions 143. Four mounting holes 147 are defined in corners of the clamping member 14 and aligned with the through holes 123 of the base plate 12 of the first heat dissipation unit 10. The clamping member 14 and the base member 12 are assembled together with the evaporating portion 42 and the parts of the connecting portions 43, 44 of the heat pipe 40 received in the U-shaped groove 121 of the base plate 12 and covered by the top portion 141 of the clamping member 14.

The second heat dissipation unit 20 is located at a lateral side of the first heat dissipation unit 10 and comprises a plurality of parallel fins 22. Each fin 22 is made of a metal sheet, and has an L-shaped configuration. The fins 22 comprise a first portion 221 located over the top surface of the graphics card 60, and a second portion 223 extending perpendicularly and downwardly from the first portion 221. The second portion 223 has a lower part (not labeled) located below the bottom surface of the graphics card 60. A through hole 225 is defined at a joint (not labeled) of the first portion 221 and the second portion 223; thus, a circular channel (not labeled) is formed in the second heat dissipation unit 20 by the through holes 225 of the fins 22. A plurality of air channels (not labeled) is defined between the fins 22 for facilitating dissipation of heat from the fins 22 to the surrounding environment. The condensing portion 45 of the heat pipe 40 is received and soldered in the channel of the second heat dissipation unit 20.

The third heat dissipation unit 30 is similar to the second heat dissipation unit 20 and separately located at the same lengthwise side of the graphics card 60 with the second heat dissipation unit 20. The third heat dissipation unit 30 comprises a plurality of fins 32. Each fin 32 is made of a metal sheet, and has an L-shaped configuration. The fins 32 comprise a first portion 321 located over the top surface of the graphics card 60, and a second portion 323 extending perpendicularly and downwardly from the first portion 321. The second portion 323 has a lower part (not labeled) located below the bottom surface of the graphics card 60. A through hole 325 is defined at a joint (not labeled) of the first portion 321 and the second portion 323; thus, a circular channel (not labeled) is formed in the third heat dissipation unit 30 by the through holes 325 of the fins 32. A plurality of air channels (not labeled) is defined between the fins 32 for facilitating dissipation of heat from the fins 32 to the surrounding environment. The condensing portion 46 of the heat pipe 40 is received and soldered in the channel of the third heat dissipation unit 30.

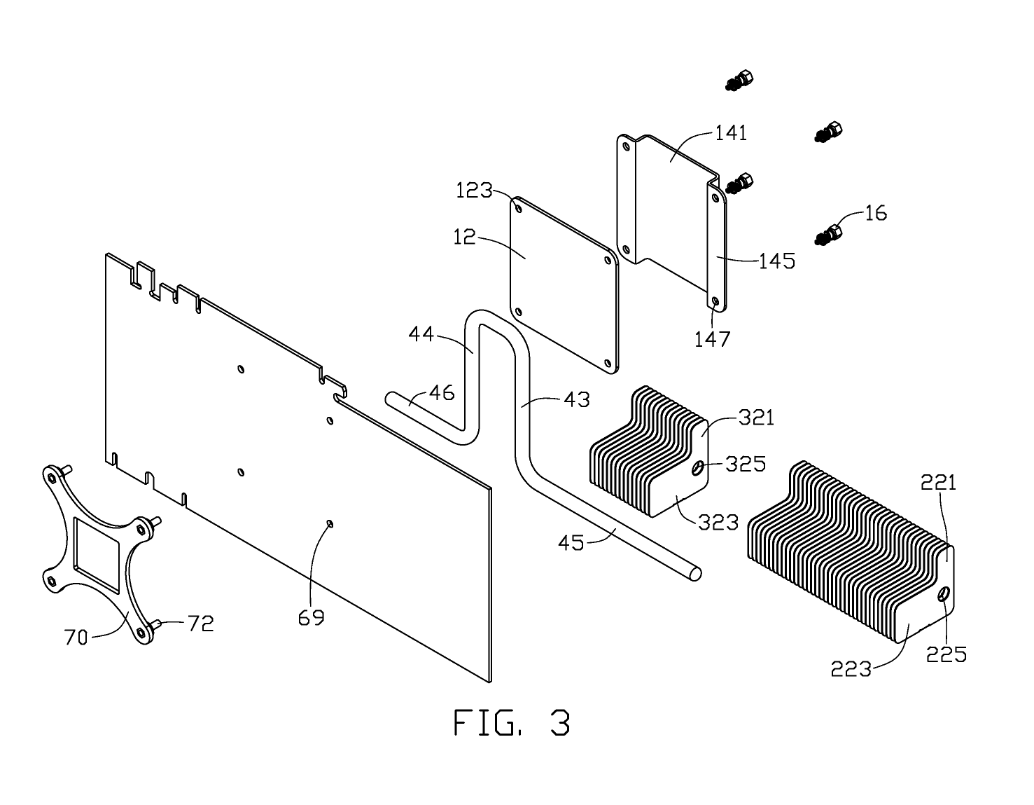

Referring to FIG. 3, the heat dissipation device further comprises a back plate 70 to reinforce the graphics card 60. The back plate 70 is positioned below the bottom surface of the graphics card 60. The back plate 70 is cross-shaped and forms four nuts 72 thereon. The screws 16 extend through the mounting holes 147 of the clamping member 14, the through holes 123 of the base plate 12 of the first heat dissipation unit 10, the through holes 69 of the graphics card 60 and threadedly engage in the nuts 72 of the back plate 70 to fasten the first heat dissipation unit 10 and the back plate 70 to the graphics card 60. Thus, the heat dissipation device is mounted to the graphics card 60.

After the heat dissipation device is mounted to the graphics card 60, the heat pipe 40 is able to transfer heat from the first heat dissipation unit 10, which is attached on the electronic component 50, to the second and the third heat dissipation unit 20, 30 which are separated from the electronic component 50.

In the present invention, since the fins 22, 32 extend above and below the top and bottom surfaces of the graphics card 60, a space between the graphics card 60 and neighboring cards can be efficiently used, thereby to enhance the heat dissipation effectiveness of the heat dissipation device. Furthermore, the heat pipe 40 has two oppositely extended condensing portions 45, 46 engaging in the second and third heat dissipation units 20, 30 which are positioned along the lengthwise side of the graphics card 60, whereby the heat absorbed by the evaporating portion 42 from the electronic component 50 can be timely dissipated.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device for dissipating heat generated by an electronic component mounted on an add-on card, the heat dissipation device comprising:
a first heat dissipation unit attached to a top surface of the electronic component, thereby absorbing heat from the electronic component;
a second heat dissipation unit located at a lengthwise side of the graphics card, comprising a first portion located over a top surface of the add-on card, and a second portion extending perpendicularly and downwardly from the first portion to a position beyond a bottom surface of the add-on card;
a third heat dissipation unit located at the lengthwise side of the graphics card; and
a heat pipe comprising an evaporating portion received in the first heat dissipation unit and thermally connecting therewith, a first condensing portion extending through the second heat dissipation unit at a joint of the first portion and the second portion of the second heat dissipation unit, and a second condensing portion extending through and thermally engaging with the third heat dissipation unit.

2. The heat dissipation device as claimed in claim 1, wherein the second and third condensing portions of the heat pipe extend in opposite directions.

3. The heat dissipation device as claimed in claim 2, wherein the second heat dissipation unit comprises a plurality of fins and each of the fins is L-shaped.

4. The heat dissipation device as claimed in claim 1, wherein the first heat dissipation unit comprises a base plate and a clamping member positioned on the base plate, and the evaporating portion of the heat pipe is sandwiched between the base plate and the clamping member.

5. The heat dissipation device as claimed in claim 1, wherein the third heat dissipation unit comprises a plurality of fins and each of the fins is L-shaped.

6. The heat dissipation device as claimed in claim 1, wherein the heat pipe further comprises a pair of parallel connecting portions extending from opposite ends of the evaporating portion and connecting the evaporating portion with the first and second condensing portions.

7. The heat dissipation device as claimed in claim 6, wherein the third heat dissipation unit is shorter than the second heat dissipation unit.

8. The heat dissipation device as claimed in claim 6, wherein the evaporating portion and the connecting portions of the heat pipe cooperatively form a U-shaped configuration.

9. The heat dissipation device as claimed in claim 6, wherein the evaporating portion of the heat pipe is straight.

10. The heat dissipation device as claimed in claim 1, wherein the first and second condensing portions of the heat pipe are separately located at the lengthwise side of the add-on card and oriented towards opposite directions.

11. The heat dissipation device as claimed in claim 1 further comprising a back plate located below the bottom surface of the add-on card, and screws extending through the first heat dissipation unit and the add-on card and engaging with the back plate to fasten the heat dissipation device to the add-on card.

12. An electronic assembly comprising:
an add-on card having a first surface and a second surface opposite the first surface;
an electronic component mounted on the first surface of the add-on card; and
a heat dissipation device comprising:
a first heat dissipation unit mounted on the first surface of the add-on card and thermally engaging with the electronic component;
a second heat dissipation unit comprising a first portion located at a top surface of the add card, and a second portion extending from the first portion and located below a bottom surface of the add-on card; and
a heat pipe comprising an evaporating portion received in the first heat dissipation unit, and a condensing portion extending through the second heat dissipation unit at a joint of the first and the second portions of the second heat dissipation unit.

13. The electronic assembly as claimed in claim 12, wherein the second portion of the second heat dissipation unit is located at a side of the add-on card.

14. The electronic assembly as claimed in claim 13, wherein the second heat dissipation unit comprises a plurality of fins and each of the fins is L-shaped.

15. The electronic assembly as claimed in claim 13, wherein the first heat dissipation unit comprises a base plate and a clamping member positioned on the base plate, and the clamping member has a flat top portion, and the evaporating portion of the heat pipe is sandwiched between the base plate and top portion of the clamping member.

16. The electronic assembly as claimed in claim 15, wherein the heat pipe further comprises a connecting portion extending from an end of the evaporating portion and interconnecting the evaporating portion and the condensing portion of the heat pipe.

17. An electronic assembly comprising:
a graphics card having a graphics processing unit thereon; and
a heat dissipation device comprising:
a base plate thermally engaging with the graphics processing unit;
a first fin unit located at a lengthwise side of the graphics card;
a second find unit located at the lengthwise side of the graphics card and separated from the first fin unit; and
a heat pipe having an evaporating portion thermally connecting with the base plate, a first condensing portion extending through and thermally engaging with the first fin unit and a second condensing portion extending through and thermally engaging with the second fin unit;
wherein the first and second condensing portions extend from the evaporating portion along opposite directions.

18. The electronic assembly as claimed in claim 17, wherein the first and second fin units each have a substantially L-shaped configuration with a first portion located over a top surface of the graphics card on which the graphics processing unit is mounted and a second portion extending downwardly from the first portion to a position beyond a bottom surface of the graphics card.

19. The electronic assembly as claimed in claim 18, wherein the heat pipe has two connecting portions connecting the evaporating portion and the condensing portions, the evaporating portion and the connecting portions cooperatively forming a U-shaped configuration.

20. The electronic assembly as claimed in claim 19 further comprising a back plate attached to the bottom surface of the graphics card, screws being extended through the base plate, the graphics card to connect with the back plate thereby to securely mount the base plate and the back plate to the graphics card.
